(19) United States
(12) Patent Application Publication
(10) Pub. No.: US 2016/0105152 A1
(43) Pub. Date: Apr. 14, 2016

(54) Reconfigurable Power Amplification Device and an Integrated Circuit Including Such a Device

(71) Applicants: Thales, Courbevoie (FR); Universite De Bordeaux, Bordeaux (FR); Institut Polytechnique De Bordeaux, Talence Cedex (FR); Centre National De La Recherche Scientifique ( C.N.R.S.), Paris (FR)

(72) Inventors: Benoit Mallet-Guy, Pessac (FR); Victor Dupuy, Bordeaux (FR); Jean-Philippe Antoine Plaze, Elancourt (FR); Claude Jean Auric, Elancourt (FR); Yves Manusco, Elancourt (FR); Eric Kerherve, Pessac (FR); Nathalie Deltimple, Pessac (FR)

(21) Appl. No.: 14/879,298

(22) Filed: Oct. 9, 2015

(30) Foreign Application Priority Data
Oct. 9, 2014 (FR) 1402274

(51) Int. Cl. H03F 1/02; H03F 3/217; H03F 3/21

(52) U.S. Cl. CPC H03F 1/0205; H03F 3/211; H03F 3/217; H03F 2203/21109

(57) ABSTRACT

This reconfigurable power amplification device (110) includes, between an input (112) and an output (114), a first power channel (115) and a second power channel (117), and a switching means for dynamically selecting either one of the power channels in order to forward power between the input and the output of the device. The switching means includes an output coupler (132) able to operate in a coupling mode or in a combination mode, and a circuit (136, 138) for controlling the coupler so as to have it operate either in a coupling mode so that the power path passes through the second power channel, or in a combination mode so that the power path passes through the first power channel. Application to an integrated circuit in hybrid or MMIC technology.

### CROSS-REFERENCE TO RELATED APPLICATIONS

The present application is a non-provisional application claiming the benefit of FR 1402274, filed Oct. 9, 2014, which is incorporated herein by reference in its entirety.

### FIELD OF THE INVENTION

The field of the invention is that of power amplification devices and more particularly reconfigurable power amplification devices.

### BACKGROUND OF INVENTION

A reconfigurable power amplification device from the state of the art is illustrated in FIG. 1.

The device 10 is a component of the <<dipole>> type, including an input 12 and an output 14.

Between the input 12 and the output 14, the device 10 includes first and second power channels 15 and 17, characterized by different amplification properties. For example, the first channel 15 includes a first amplifier 16 and the second channel 17 includes a second amplifier 18, the first and second amplifiers having different amplification coefficients. More generally, the first and second power channels may have different properties in terms of delivered power, but also in terms of operating frequency.

In order to forward the power along the first channel 15 or the second channel 17, the device 10 includes switching means. The switching means include an input switch 22 and an output switch 24.

In a first position of the input switch 22, respectively of the output switch 24, the input 12, respectively the output 14, of the device 10 is connected to the input, respectively to the output, of the first amplifier 16. In a second position of the input switch 22, respectively of the output switch 24, the input 12, respectively the output 14, of the device 10 is connected to the input terminal, respectively output terminal, of the second amplifier 18.

The position of each switch 22, 24, is controlled according to the control signal level Sc applied to a control terminal of the switch. The control signals are synchronized so that the input 22 and output 24 switches are in their first position or in their second position simultaneously.

Thus, in the first position of the input 22 and output 24 switches, the power applied on the input 12 is forwarded along the first channel 15 so as to be amplified by the first amplifier 16. An amplified power is delivered on the output 14 of the device 10. The first channel 15 is therefore conducting, while the second channel 17 is in an open circuit.

On the other hand, when both input 22 and output 24 switches are in their second position, the power applied on the input 12 is forwarded along the second channel 17 so as to be amplified by the second amplifier 18. The thereby generated power is delivered on the output 14 of the device 10. The first channel 15 is then in an open circuit, while the second channel 17 is conducting.

For example, if the amplifiers 16 and 18 have different properties in operating frequency band, a suitable control signal Sc is applied to the input 22 and output 24 switches so as to have them switch from their first position to their second position, so that the power path corresponds to the second power channel, in order to increase the level of the power delivered by the device 10 in the desired operating frequency band. The device 10 is then reconfigurable depending on the operating frequency band of the signal to be amplified.

The architecture of this device gives the possibility of having a component of the dipole type including a single global input and a single global output and which may operate under two alternative configurations, as soon as the first and second channels have different properties.

However, such a device has two major and irreducible drawbacks, since they are related to the architecture of the device.

The first problem lies in the fact that an input or output switch, has a power handling limit. Beyond a threshold power, a switch changes its operating state, which has the consequence of increasing the losses through this switch. In the architecture shown above, it is the output switch, exposed to greater powers, which risks attaining its power handling limit first. Because of these losses, the overall yield of the device is reduced.

Concomitantly to a change in the operating state of a switch, a reduction in the electric insulation of the channel occurs in an open circuit. In an extreme case, the switch is damaged and can no longer fulfill its function of directing the power to or from either one of the power channels.

The second problem affecting the known reconfigurable power amplification devices lies in the fact that the switches generate losses during passing of the current. Thus, the power delivered on the output terminal by the first or the second amplifier is not entirely found again on the output 14 of the device 10. Similarly, the power applied on the input 12 is not entirely found again on the input terminal of the first or second amplifier. A portion of the power is lost through the switch, in particular through the output switch. This second problem is particularly damageable for a high yield reconfigurable power amplification device. The overall yield of the device will be all the lower since the losses generated by each switch will be significant.

The object of the invention is therefore to overcome the aforementioned problems.

### SUMMARY OF INVENTION

For this purpose, the object of the invention is a device, a reconfigurable power amplification device, including, between an input and an output, a first power channel and a second power channel, and a switching means in order to dynamically select either one of the power channels for forwarding power between the input and the output of the device, characterized in that the switching means includes an output coupler able to selectively operate in a coupling mode or in a combination mode, and a circuit for controlling the coupler so as to have it operate either in a coupling mode, so that the power path passes through the second power channel, or in a combination mode so that the power path passes through the first power channel.

The device according to the invention allows switching between either one of the power channels without the switching means generating any loss, or limiting their power handling.

According to other advantageous aspects of the invention, the device comprises one or more of the following features, taken individually or according to all the technically possible combinations:
the output coupler includes a direct input port and a coupled input port connected to the first power channel, a coupled output port connected to the second power channel, and a direct output port connected to the output of the device;
the direct and coupled input ports of the output coupler are connected to ground via first control switches, and the coupled output port of the output coupler is connected to ground, via a second switch, the coupling mode being obtained by placing the second switch in an open position and by placing the first switches in a closed position, while the combination mode is obtained by placing the second switch in a closed position and by placing the first switches in an open position;
the first channel includes a pair of first amplifiers in parallel with each other, the output terminal of an amplifier from among the first amplifiers being connected to the direct input port of the output coupler, the output terminal of the other amplifier from among the first amplifiers being connected to the input port coupled with the output coupler;
the signals at the output of each of the first amplifiers of the first power channel are in quadrature relatively to each other and preferably have the same amplitude;
the signals applied on the input terminal of each of the first amplifiers of the first power channel are respectively delivered through a coupled input port and through a direct output port of an input coupler, for which one direct input port is connected to the input of the device and for which a coupled output port is connected to a load, so as to operate in a coupling mode;
the switching means further includes an input switch which, in a first position connects the input of the device to the first power channel and, in a second position, the input to the second power channel, the input switch and the means for controlling the output coupler being controlled in a synchronized way;
the amplification properties of the first and second power channels are different in terms of gain and/or of pass bandwidth; and
the first power channel corresponds to operation of the device in a narrow pass bandwidth and with high power, while the second power channel corresponds to operation of the device in a wide pass bandwidth and at medium power.

The invention also relates to an integrated circuit in hybrid or MMIC technology, including a reconfigurable power amplification device as defined above.

The invention will be better understood upon reading the description which follows of a particular embodiment, only given as an illustrative example and not as a limitation, the description being made with reference to the appended drawings.

### BRIEF DESCRIPTION OF THE DRAWINGS

FIG. 1 is a schematic illustration of a reconfigurable power amplification device according to the prior art;

FIG. 2 is a schematic illustration of a reconfigurable power amplification device according to the present invention;

FIG. 3 is a schematic illustration of the coupled operating mode of a LANGE coupler integrated into the device of FIG. 2;

FIG. 4 is a schematic illustration of the combined operating mode of a LANGE coupler integrated into the device of FIG. 2;

FIG. 5 is an illustrative graph of the operation of the device of FIG. 2;

FIG. 6 is an illustrative graph of the operation of the device of FIG. 2; and

FIG. 7 is an illustrative graph of the operation of the device of FIG. 2.

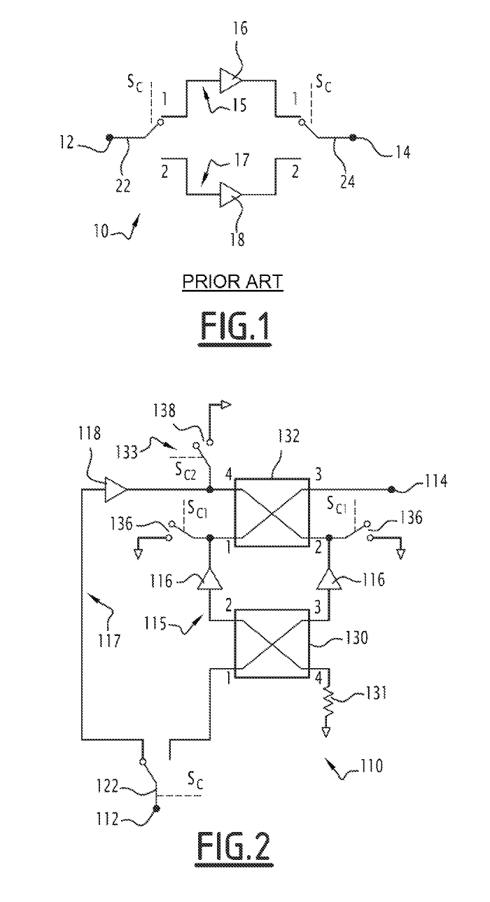

### DETAILED DESCRIPTION OF INVENTION

FIG. 2 illustrates a presently preferred embodiment of a reconfigurable power amplification device 110.

The device 110 is a component of the dipole type, including a global input 112 and a global output 114.

The device 110 includes two power channels positioned in parallel with each other and totally independent of each other. Alternatively, the device includes N power channels, positioned in parallel with each other and totally independent of each other. Each power channel has amplification properties different from each other or from each other power channel.

The first power channel 115 of the device 110 includes an input coupler 130 and amplification means including two first amplifiers 116 identical with each other and positioned in parallel with each other.

The second power channel 117 includes amplification means including a second amplifier 118.

Alternatively, the amplification means of each power channel are formed by the association of various amplification and preprocessing components of the current flowing over the corresponding power channel. For example, in addition to a power amplifier, the amplification means may include a filter so as to select a operating frequency of the corresponding power channel.

For switching the power path between the input 112 and the output 114, along the first channel 115 or the second channel 117, the device 110 includes switching means.

The switching means include an input switch 122, able to connect in a first position the first channel 115 to the input 112 and in a second position to connect the second channel 117 to the input 112. The position of the input switch 122 is controlled by the level of a control signal Sc applied on a control terminal of the input switch 122.

The switching means further include an output coupler 132 and a circuit 133 for controlling the operation mode of the output coupler 132.

The control circuit 133 includes three switches, a pair of first switches 136, and a second switch 138, respectively. The open or closed position of each switch 136, 138 allows dynamic modification of the operating mode of the output coupler 132 and selective connection of the first channel or of the second channel, to the output 114.

The output coupler 132 is able to operate in a coupling mode or in a combination mode.

The output coupler 132 is preferably a passive component with four ports conventionally including a direct input port 1, a coupled input port 2, a direct output port 3 and a coupled output port 4.

Advantageously, the output coupler 132 is a quadrature coupler, able to provide from an input signal, two output signals in phase quadrature relatively to each other.

The output coupler 132 is preferably a Lange coupler.

Such a component is conventionally used in a balanced coupling mode in order to fulfill the coupler function as shown in the article J. Lange “Interdigitated Stripline Quadrature Hybrid (Correspondence)”, IEEE Transactions on Microwave Theory and Techniques, Vol. 17, no. 12, pp. 1150, 1151, December 1969.

In a balanced coupling mode, the coupled output port 4 is connected to a load, in particular a 50 Ohm impedance, in order to allow rated operation of the coupler. An input signal is applied on the direct input port 1. Output signals are then recovered on the coupled input port 2 and on the direct output port 3. Both of these two output signals have the same amplitude (that of the input signal), but are phase-shifted by 90° relatively to each other.

Such a component is also conventionally used in a balanced combination mode for fulfilling the power combination function, as shown in the article of M. Satoshi et al. <<Over 10 W C-Ku band GaN MMIC non-uniform distributed power amplifier with broadband couplers>>, 2010 IEEE MTT-S International Microwave Symposium Digest (MTT), pp. 1388, 1391, 23-28 May 2010.

In a balanced combination mode, once again, the coupled output port 4 is connected to a load, in particular a 50 Ohm impedance, for balancing the coupler. The direct 1 and coupled 2 input ports receive input signals. The direct output port 3 is the one on which the output signal is recovered. This output signal corresponds to the sum of the signals applied at the input.

The power recovered on the direct output port 3 will be maximum when the signals applied on the direct 1 and coupled 2 input ports are of the same amplitude and in phase quadrature relatively to each other. Indeed, the direct input port 1 is directly connected to the direct output port 3, while the coupled input port 2 is only connected to the direct output port 3 by electromagnetic coupling which introduces a phase-shift of 90°. The power recombination will therefore be maximum on the direct output port 3 if the signals on the input ports 1 and 2 are in quadrature.

In the device 110, the output coupler 132 is used either in a coupling mode or in a combination mode, in order to achieve the function for switching the power path through either one of the power channels.

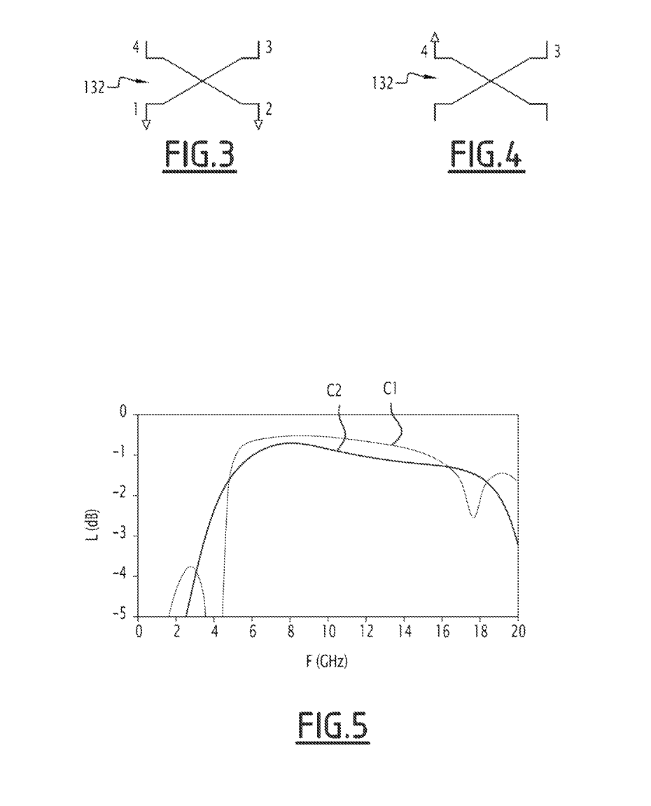

On the diagram of FIG. 3, the coupler 132 is in the coupling mode: the direct 1 and coupled 2 input ports are short-circuited to ground. The signal applied at the input of the coupler 132 is applied on the coupled output port 4, which, in the standard use, is connected to a load. The output signal is collected on the direct output port 3, which forms the output of the coupler 132. In this operating mode, the connection of the ports 1 and 2 to ground gives the possibility of ensuring maximum power transfer between the two other ports of the coupler 132.

On the diagram of FIG. 4, the coupler 132 is in the combination mode: while the coupled output port 4 is connected to ground, input signals are applied on the direct 1 and coupled 2 input ports. These input signals are in phase quadrature relatively to each other. An output signal is collected on the direct output port 3 of the coupler. The output signal is equal to the sum of the two input signals. The coupler 132 is used here as standard power combining device, except for the fact that the coupled output port 4 is no longer connected to a load, but short-circuited to ground.

Again with reference to FIG. 2, the output terminal of a first amplifier 116 is connected to the direct input port 1 of the output coupler 132, the output terminal of the other first amplifier 136 is connected to the coupled input port 2, the output terminal of the second amplifier 118 is connected to the coupled output port 4 and the output 114 is connected to the direct output port 3.

Each first switch 136 is placed between an input pole 1 or 2 of the coupler 132 and the ground, as a shunt of the output terminal of one of the first amplifiers 116.

The second switch 138 is placed between the coupled output pole 4 of the coupler 132 and ground, as a shunt on the output terminal of the second amplifier 118.

Each switch is controlled by a control signal Sc1, Sc2, for example a control voltage, for passing from the closed position to the open position and vice versa. In the open position, each switch has an open circuit behavior, while in the closed position it becomes conducting and has the behavior of a short-circuit to ground.

If the first switches 136 are in a closed position while the second switch 138 is in an open position, the coupler 132 operates in a coupled mode, the conducting channel is then the second channel 117. On the other hand, if the first switches are in an open position and the second switch is in a closed position, the coupler 132 operates in a combination mode, the conducting channel then being the first channel 115.

The input coupler 130, which operates in a standard coupling mode, advantageously allows generation of signals which are of the same amplitude and in quadrature relatively to each other. For this, the input coupler 130 has its direct input port 1 connected to the input 112 of the device, via the input switch 122, its coupled output port 4 connected to a load 131, such as a 50 Ohm impedance, moreover connected to ground. The input coupler 130 has its coupled input port 2 connected to the input terminal of one of the two first amplifiers 116 and its direct output port 3 connected to the input terminal of the other of the first amplifiers 116. These signals in quadrature and of the same amplitude, once they are amplified, are applied to the input of the output coupler 132, operating in a combination mode.

Thus, by suitably adjusting the control signals of the switches 136 and 138, and of the input switch 122, it is possible to dynamically select the conducting power channel between the input 112 and the output 114 of the device 110, in order to make a selection between the amplification properties of the first power channel or those of the second power channel. The device 110 fits well to the need of a reconfigurable power amplifier, i.e. there are two possible distinct paths for a single and same input and a single and same output, with a dynamic switching means between both paths.

FIGS. 5 to 7 result from simulations.

FIG. 5 illustrates the losses generated through the output coupler 132 in the coupling mode (curve C2) and in the combination mode (curve C1).

It is seen that the losses are minimum in the combination mode, while the pass bandwidth is maximum in the coupling mode.

Accordingly and since the combination mode corresponds to application of the power on two inputs of the output coupler 132, the combination operating mode will be preferred for the power channel along which maximization of the power delivered at the output is sought, i.e. with a very high yield, while the coupling operating mode will be dedicated to the power channel along which having the widest pass bandwidth is sought.

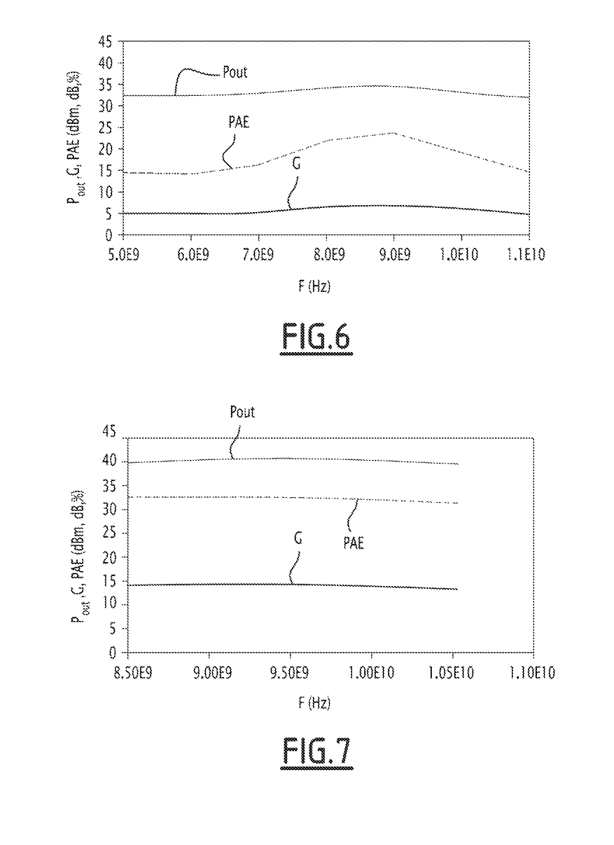

FIGS. 6 and 7 illustrate the overall power behavior of the device 110. In FIG. 6, in the coupling mode of the output coupler, i.e. along the second channel 117, an output power Pout of more than 32 dBm is measured with an added power yield PAE of more than 14%, over a frequency band F between 5 GHz and 11 GHz.

In FIG. 7, in the combination mode of the output coupler, i.e. along the first channel 115, a high gain G, an output power Pout of more than 40 dBm (10 W) are measured with an added power yield PAE of more than 33%, over a frequency band F ranging from 8 to 10 GHz.

Thus, the device according to the invention applies, for switching between the power channels, a passive component of the Lange coupler type and switches which are positioned in parallel with the power path. The switching between the different power channels is achieved by doing without the application of switches placed in series in the power path, at the very least at the output, where the power is substantial.

Indeed it should be noted that in the embodiment of FIG. 2, the input switch 112 is integrated in series with the power path, in a conventional way. However, on the side of the input of the amplification device, there are no strong constraints in terms of power handling, this switch being placed before the power amplification stages. Alternatively, a coupler similar to the output coupler 132 and controlled in a way similar to that of the output coupler 132 by a plurality of switches shunting the power path may for example be applied instead of the input switch 122.

As the switches are positioned in parallel with the power path, they are no longer covered by the power flowing along the conducting channel. Thus, the power limitation of the switches is not attained and the power handling limit of the device as a whole is pushed back. The power which may then be switched is no longer limited by the power handling of the switches.

Further, as the switches are no longer on the power path, the insertion losses inherent to the use of such a component no longer have any impact on the overall yield of the device, nor on the power level delivered at the output.

Low losses are nevertheless caused by the parallel switches 136 and 138 because of their non-ideality, but these losses remain disproportionate with the case when the switches are placed in series with the power paths.

Many other alternatives of the circuit of FIG. 2 may be contemplated by one skilled in the art.

The device may in particular include more than two power channels and positions of the switching means for selecting the conducting channel. The switching means at the output include for example a plurality of couplers placed in cascade with each other.

In the embodiment described in detail, when the power path passes through the first channel, the signal is applied on two inputs of the coupler 132 operating as a combination circuit. It is therefore advantageous to place in parallel two amplifiers so as to double the power generated by the corresponding power channel. But this is not mandatory and other embodiments of the first channel may be contemplated.

The device according to the invention will find applications within the scope of wireless communication systems, more particularly electronic warfare systems or military radar systems.

A device according to the invention meets the problem of the design of reconfigurable power amplifiers as regards power and/or operating frequency in MMIC (for <<monolithic microwave integrated circuit>>, GaN or GaAs) technology or in hybrid technology.

In particular, a coupler of the Lange coupler type has a sufficiently reduced size so as to be able to be integrated into a circuit, in particular an MMIC circuit or in a hybrid technology.

What is claimed is:

1. A reconfigurable power amplification device including, between an input and an output, a first power channel and a second power channel, positioned in parallel with each other and independent of each other, and a switching means for dynamically selecting either one of the power channels in order to forward a power between the input and the output of the device, characterized in that the switching means includes an output coupler capable of operating in a coupling mode or in a combination mode, and a control circuit of the output coupler so as to have said output coupler operating either in said coupling mode, so that a power path passes through the second power channel, or in said combination mode so that a power path passes through the first power channel.

2. The device according to claim 1, wherein the output coupler includes a direct input port and a coupled input port connected to the first power channel, a coupled output port connected to the second power channel, and a direct output port connected to the output of the device.

3. The device according to claim 2, wherein the direct input port and the coupled input port of the output coupler are connected to a ground via first controlled switches, and the coupled output port of the output coupler is connected to the ground, via a second switch, the coupling mode being obtained by placing the second switch in an open position and by placing the first switches in a closed position, and the combination mode being obtained by placing the second switch in a closed position and by placing the first switches in an open position.

4. The device according to claim 3, wherein the first channel includes a pair of first amplifiers in parallel with each other, the output terminal of an amplifier from among the first amplifiers being connected to the direct input port of the output coupler, the output terminal of the other amplifier from among the first amplifiers being connected to the coupled input port of the output coupler.

5. The device according to claim 4, wherein the output signals of each of the first amplifiers of the first power channel are in quadrature with each other and preferably have the same amplitude.

6. The device according to claim 5, wherein the signals applied on the input terminal of each of the first amplifiers of the first power channel are respectively delivered through a coupled input port and through a direct output port of an input coupler, for which a direct input port of said input coupler being connected to the input of the device and a coupled output port of said input coupler being connected to a load, so as to operate in a coupling mode.

7. The device according claim 1, wherein the switching means further includes an input switch which, in a first position, connects an input of the device to the first power channel and, in a second position, an input to the second power channel, the input switch and the means for controlling the output coupler being controlled in a synchronized way.

8. The device according to claim 1, wherein amplification properties of the first and second power channels are different in terms of gain and/or of bandwidth.

9. The device according to claim 8, wherein the first power channel corresponds to operate the device in a narrow bandwidth and with a high power, while the second power channel corresponds to operate the device in a wide bandwidth and at a medium power.

10. An integrated circuit in hybrid or MMIC technology, the integrated circuit comprising a reconfigurable power amplification device, wherein said device comprises, includes, between an input and an output, a first power channel and a second power channel, positioned in parallel with each other and independent of each other, and a switching means for dynamically selecting either one of the power channels in order to forward a power between the input and the output of the device, characterized in that the switching means includes an output coupler capable of operating in a coupling mode or in a combination mode, and a control circuit of the output coupler so as to have said output coupler operating either in said coupling mode, so that a power path passes through the second power channel, or in said combination mode so that a power path passes through the first power channel.

11. The integrated circuit according to claim 10, wherein the output coupler includes a direct input port and a coupled input port connected to the first power channel, a coupled output port connected to the second power channel, and a direct output port connected to the output of the device.

12. The integrated circuit according to claim 11, wherein the direct input port and the coupled input port of the output coupler are connected to a ground via first controlled switches, and the coupled output port of the output coupler is connected to the ground, via a second switch, the coupling mode being obtained by placing the second switch in an open position and by placing the first switches in a closed position, and the combination mode being obtained by placing the second switch in a closed position and by placing the first switches in an open position.

13. The integrated circuit according to claim 12, wherein the first channel includes a pair of first amplifiers in parallel with each other, the output terminal of an amplifier from among the first amplifiers being connected to the direct input port of the output coupler, the output terminal of the other amplifier from among the first amplifiers being connected to the coupled input port of the output coupler.

14. The integrated circuit according to claim 13, wherein the output signals of each of the first amplifiers of the first power channel are in quadrature with each other and preferably have the same amplitude.

15. The integrated circuit according to claim 14, wherein the signals applied on the input terminal of each of the first amplifiers of the first power channel are respectively delivered through a coupled input port and through a direct output port of an input coupler, for which a direct input port of said input coupler being connected to the input of the device and a coupled output port of said input coupler being connected to a load, so as to operate in a coupling mode.

16. The integrated circuit according claim 10, wherein the switching means further includes an input switch which, in a first position, connects an input of the device to the first power channel and, in a second position, an input to the second power channel, the input switch and the means for controlling the output coupler being controlled in a synchronized way.

17. The integrated circuit according to claim 10, wherein amplification properties of the first and second power channels are different in terms of gain and/or of bandwidth.

18. The integrated circuit according to claim 17, wherein the first power channel corresponds to operate the device in a narrow bandwidth and with a high power, while the second power channel corresponds to operate the device in a wide bandwidth and at a medium power.
